(19) United States
(12) Patent Application Publication
(10) Pub. No.: US 2005/0141285 A1
(43) Pub. Date: Jun. 30, 2005

(54) SONOS device and fabricating method thereof

(75) Inventor: Jin Hyo Jung, Bucheon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/022,878

(22) Filed: Dec. 28, 2004

(30) Foreign Application Priority Data
Dec. 31, 2003 (KR) P 2003-0101058

(51) Int. Cl. G11C 11/34

(52) U.S. Cl. 365/185.29

(57) ABSTRACT

The present invention provides a SONOS device and fabricating method thereof, by which the thickness of the tunnel oxide layer is increased to enhance the retention characteristic of the SONOS device and by which the program, erase, and retention characteristics are simultaneously enhanced in a manner of performing a program by hot electron injection and an erase by photon-assisted erase. The present invention includes a tunnel oxide layer formed 40˜150 Å thick on a first conductive type silicon substrate, a trap nitride layer on the tunnel oxide layer, a block oxide layer formed 40˜150 Å thick on the trap nitride layer, a first conductive type polysilicon gate on the block oxide layer, and a source and drain formed in the substrate adjacent to both sides of the tunnel oxide layer, respectively.

This application claims the benefit of the Korean Application No. P2003-0101058 filed on Dec. 31, 2003, which is hereby incorporated by reference.

### BACKGROUND OF THE INVENTION

1. Field of the Invention

The present invention relates to a SONOS (silicon oxide nitride oxide semiconductor) device, and more particularly, to a SONOS device and fabricating method thereof, by which program, erase, and retention characteristics are simultaneously enhanced in a manner of performing a program by hot electron injection and an erase by photon-assisted erase.

2. Discussion of the Related Art

Generally, semiconductor memory devices are categorized into volatile memories and non-volatile memories. Most of the volatile memories are RAMS such as DRAM (dynamic random access memory), SRAM (static random access memory), etc., enabling data input and storage on power impression. Yet, if the power is cut off, data stored in the memory is evaporated and gone. On the other hand, most of the non-volatile memories are ROMs (read only memories) are characterized in the capability of storing data without power impression.

Currently, in aspect of process technologies, the non-volatile memory devices are categorized into a floating gate series and an MIS (metal insulator semiconductor) series having at least two kinds of dielectrics stacked therein.

The floating gate series memory device implements the memory characteristics using potential wells. And, ETOX (EPROM tunnel oxide) structure applied to the current flash EEPROM (electrically erasable programmable read only memory) is the most representative.

On the other hand, the MIS series memory device performs a memory function using traps existing on a dielectric bulk, a dielectric-dielectric interface, and a dielectric-semiconductor interface. And, MONOS (metal ONO semiconductor) and SONOS (silicon ONO semiconductor) structures applied to the current flash EEPROM are the most representative.

A SONOS memory device according to a related art consists of tunnel oxide, trap nitride, and block oxide layers stacked on a P type silicon substrate and a gate on the block oxide layer.

In case of the SONOS memory device, a program, which is carried out in a manner of transporting electrons by F-N (Fowler-Nordheim) tunneling or direct tunneling to trap the electrons in a trap site existing within the trap nitride layer, raises a threshold voltage. And, an erase, which is carried out in a manner of draining electrons to a P type silicon substrate by F-N tunneling, direct tunneling, trap assisted tunneling, or the like, lowers the threshold voltage.

However, in the related art SONOS device using the tunneling for both of the program and erase, a thin tunneling oxide should be deposited about 20 Å thick to be provided with appropriate program and erase speeds, whereby a retention characteristic is not good.

In order to overcome such a disadvantage of the related art SONOS device, a thickness of a tunneling oxide layer is raised, a program adopts hot electron injection, and an erase adopts hot hole injection. Yet, in such a case, the retention characteristic is improved but program endurance is abruptly degraded due to hot hole injection.

### SUMMARY OF THE INVENTION

Accordingly, the present invention is directed to a SONOS device and fabricating method thereof that substantially obviate one or more problems due to limitations and disadvantages of the related art.

An object of the present invention is to provide a SONOS device and fabricating method thereof, by which program, erase, and retention characteristics are simultaneously enhanced in a manner of performing a program by hot electron injection and an erase by photon-assisted erase.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a SONOS device according to the present invention includes a tunnel oxide layer formed 40˜150 Å thick on a first conductive type silicon substrate, a trap nitride layer on the tunnel oxide layer, a block oxide layer formed 40˜150 Å thick on the trap nitride layer, a first conductive type polysilicon gate on the block oxide layer, and a source and drain formed in the substrate adjacent to both sides of the tunnel oxide layer, respectively.

Preferably, the trap nitride layer is formed 50˜200 Å thick.

Preferably, a program of the SONOS device is performed by hot electron injection.

Preferably, an erase is performed by photon-assisted erase.

In another aspect of the present invention, a method of fabricating a SONOS device includes the steps of forming a tunnel oxide layer 40˜150 Å thick on a first conductive type silicon substrate, forming a trap nitride layer on the tunnel oxide layer, forming a block oxide layer 40˜150 Å thick on the trap nitride layer, forming a first conductive type polysilicon on the block oxide layer, and patterning the first conductive type polysilicon, block oxide layer, trap nitride layer, and tunnel oxide layer.

Preferably, the patterning step includes the steps of forming a photoresist pattern on the first conductive type polysilicon, etching the first conductive type polysilicon, block oxide layer, trap nitride layer, and tunnel oxide layer using the photoresist pattern as an etch mask, and removing the photoresist pattern.

Preferably, the method further includes the step of implanting second type impurities in the substrate using the patterned first conductive type polysilicon, block oxide layer, trap nitride layer, and tunnel oxide layer as an ion implantation mask to form source/drain regions.

Preferably, the trap nitride layer is formed 50˜200 Å thick.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional diagram of a SONOS device according to the present invention;

FIG. 2 is an energy band diagram of a SONOS device by hot electron injection;

FIG. 3 is an energy band diagram of a SONOS device by photon-assisted erase; and

FIG. 4 is an energy band diagram for explaining a method of removing electrons transported by F-N tunneling to a trap nitride layer from a polysilicon gate electrode by photon injection.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

FIG. 1 is a cross-sectional diagram of a SONOS device according to the present invention.

Referring to FIG. 1, a tunnel oxide layer 105, a trap nitride layer 106, a block oxide layer 107, and a gate 104 are sequentially stacked on a P type silicon substrate 101.

A source 103 and drain 102 are formed in the substrate adjacent to both sides of the gate 104, respectively.

Each of the tunnel oxide layer 105 and the block oxide layer 107 is deposited 40˜150 Å thick and the trap nitride layer 106 is deposited 50˜200 Å thick.

A method of fabricating the SONOS device is explained as follows.

First of all, a tunnel oxide is deposited 40˜150 Å thick on a first conductive type substrate.

A trap nitride layer is deposited on the tunnel oxide layer.

A block oxide layer is deposited 40˜150 Å thick on the trap nitride layer.

A first conductive type polysilicon is deposited on the block oxide layer.

Photoresist is coated on the first conductive type polysilicon. Exposure and development are carried out on the photoresist to form a photoresist pattern.

The first conductive type polysilicon, block oxide layer, trap nitride layer, and tunnel oxide layer are patterned using the photoresist pattern as an etch mask. The photoresist pattern is then removed.

Finally, ion implantation is carried out on the substrate using the patterned first conductive type polysilicon, block oxide layer, trap nitride layer, and tunnel oxide layer as an ion implantation mask, whereby source/drain region areas are formed.

An operation of the SONOS device is explained as follows.

First of all, a positive voltage of 1˜10V is applied to the drain and gate while the source and silicon substrate are grounded. If so, an inverse layer 108 including electrons is formed on a surface area of the silicon substrate.

The electrons of the inverse layer 108, which are accelerated by a drain electric field to gain energy exceeding 3.1 eV that is a conduction bandwidth difference between the silicon and the tunnel oxide layer in the vicinity 109 of the drain region, jumps the conduction band of the tunnel oxide layer to be injected into the conduction bandwidth of the trap nitride layer.

Finally, the electrons injected in the conductor bandwidth of the trap nitride layer are trapped by a trap potential existing within the trap nitride layer, thereby executing a programming operation that raises a threshold voltage of the SONOS device. In doing so, the gate and drain voltages applied on programming are set to a condition enabling hot electrons to be generated as many as possible.

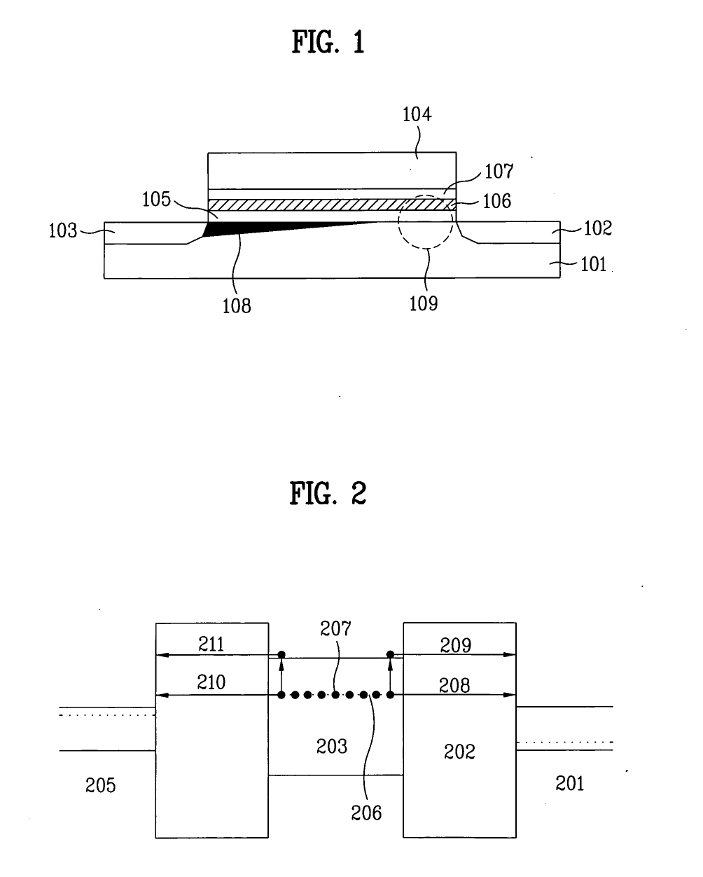

FIG. 2 is an energy band diagram of a SONOS device by hot electron injection after electrons have been trapped in the trap potential of the trap nitride layer through hot electron injection.

Referring to FIG. 2, electrons 207 trapped in a trap potential 206 of a trap nitride layer 203 drain to a silicon substrate 201 or gate electrode 205 due to a built-in electric field by tunneling methods 208 to 211 as time passes. Hence, by raising a thickness of a tunnel oxide layer 202 and a thickness of a block oxide layer 204, it is able to remarkably enhance the retention characteristic in a program mode.

There are methods for the trapped electrons to drain to the silicon substrate such as band-to-band direct tunneling, trap-assisted tunneling, thermal emission of trapped electrons, and the like. And, there are methods for the trapped electrons to drain to the gate electrode such as band-to-band direct tunneling, trap-assisted tunneling, thermal emission of trapped electrons, and the like.

Each of the tunnel and block oxide layers is used within a thickness range of 40˜150 Å. Even if the thickness of the tunnel or block oxide layer is increased, the program speed characteristic is barely affected.

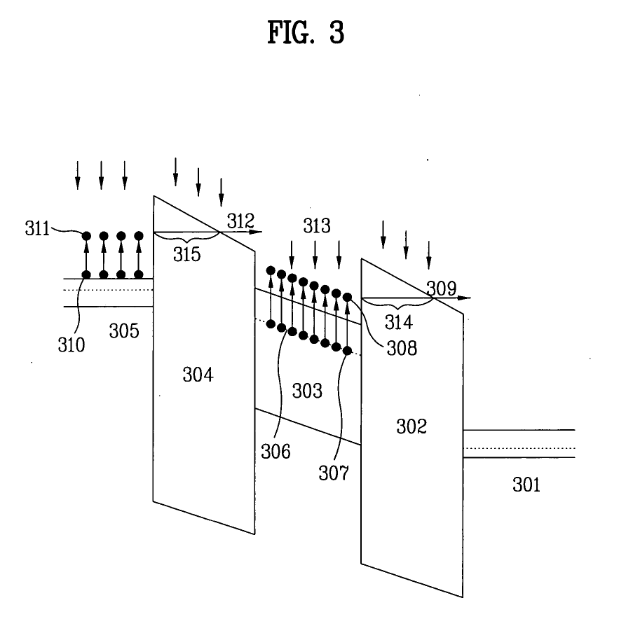

FIG. 3 is an energy band diagram of a SONOS device by photon-assisted erase.

Referring to FIG. 3, a prescribed negative voltage of (−)2˜(−)15V is applied to a gate electrode 305 of a SONOS device and a silicon substrate 301 is grounded. In ding so, photons 313 are injected in the SONOS device.

Once photons are injected outside the SONOS device, electrons 307 trapped in a trap nitride layer 303 receive photon energy to be excited over a conductor band of the trap nitride layer 303. And, the excited electrons undergo F-N tunneling 309 by an electric field applied to a gate to drain out to the substrate 301. In doing so, an F-N tunneling length 314 depends on a size of the applied electric field and an excited electron energy potential regardless of the thickness of the tunnel oxide layer 302. Hence, even if the thickness of the tunnel oxide layer 302 is increased, the erase characteristic is not greatly affected.

In this case, a wavelength of the injected photon lies within a range of 600˜20,000 nm, which can be converted to photon energy of 0.7˜2 eV, and photons corresponding to a visible or infrared ray are used.

Once the photons are injected, electrons 310 located at the conductor band of the heavily doped N type gate electrode 305 are excited as well. The excited electrons 311 undergo F-N tunneling 312 to a conductor band of the trap nitride layer 303 by the electric field applied to the gate electrode. Since an energy barrier (3.1 eV) between the gate electrode 305 and the block oxide layer 304 is much higher than an energy barrier (1.05 eV) between the trap nitride layer 303 and the tunnel oxide layer 302, a F-N tunneling length 315 is elongated. Hence, a quantity of electrons injected in the trap nitride layer from the heavily doped N type polysilicon gate electrode is negligibly smaller than that of the electrons tunneling the silicon substrate from the trap nitride layer.

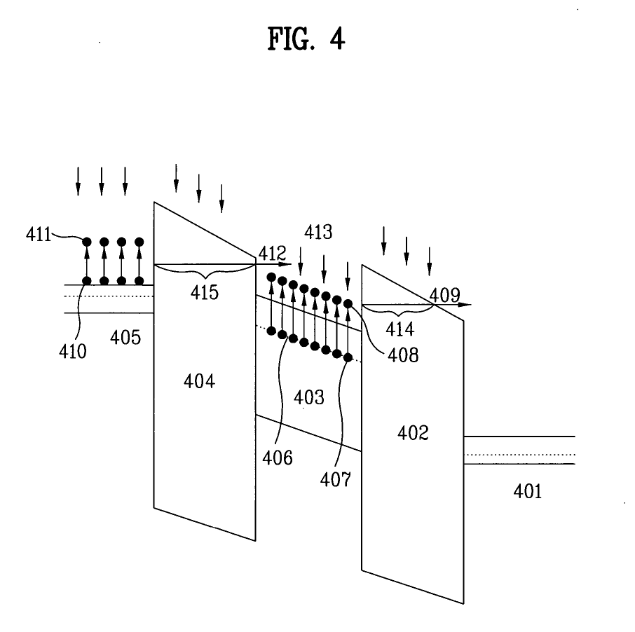

FIG. 4 is an energy band diagram for explaining a method of removing electrons transported by F-N tunneling to a trap nitride layer from a polysilicon gate electrode by photon injection.

Referring to FIG. 4, a heavily doped P type polysilicon gate 405 is used instead of a heavily doped N type polysilicon gate. Electrons 410 existing in a valence band of the heavily doped P type polysilicon gate electrode 405 receive energy of photons 413 to be excited to a conductor band of heavily doped P type polysilicon. Since a tunneling length 412 is equal to a total thickness of a block oxide layer 404 despite the excited electrons 411, it is able to effectively remove the electrons injected in a trap nitride layer 403 from the gate electrode.

As mentioned in the above explanation, the thickness of the tunnel oxide is increased to enhance the retention characteristic of the SONOS device, the program is executed at high speed regardless of the thickness on the tunnel oxide using hot electron injection, and the erase is executed regardless of the thickness of the tunnel oxide in a manner of performing F-N tunneling by exciting the electrons trapped in the trap potential of the trap nitride layer to the appropriate energy potential using light irradiation. Therefore, it is able to simultaneously enhance the program, erase, and retention characteristics of the SONOS device.

Moreover, the present invention is applicable to a floating gate device as well as the SONOS device.

Accordingly, the present invention provides the following effects or advantages.

First of all, the thickness of the tunnel oxide layer is increased to enhance the retention characteristic of the SONOS device.

Secondly, the program, erase, and retention characteristics are simultaneously enhanced in a manner of performing a program by hot electron injection and an erase by photon-assisted erase.

It will be apparent to those skilled in the art that various modifications and variations can be made in the present invention. Thus, it is intended that the present invention covers the modifications and variations of this invention provided they come within the scope of the appended claims and their equivalents.

1. A SONOS device comprising:
a tunnel oxide layer formed 40˜150 Å thick on a first conductive type silicon substrate;
a trap nitride layer on the tunnel oxide layer;
a block oxide layer formed 40˜150 Å thick on the trap nitride layer;
a first conductive type polysilicon gate on the block oxide layer; and
a source and drain formed in the substrate adjacent to both sides of the tunnel oxide layer, respectively.

2. The SONOS device of claim 1, wherein the trap nitride layer is formed 50˜200 Å thick.

3. The SONOS device of claim 1, wherein a program of the SONOS device is performed by hot electron injection.

4. The SONOS device of claim 1, wherein an erase is performed by photon-assisted erase.

5. A method of fabricating a SONOS device, comprising the steps of:
forming a tunnel oxide layer 40˜150 Å thick on a first conductive type silicon substrate;
forming a trap nitride layer on the tunnel oxide layer;
forming a block oxide layer 40˜150 Å thick on the trap nitride layer;
forming a first conductive type polysilicon on the block oxide layer; and
patterning the first conductive type polysilicon, block oxide layer, trap nitride layer, and tunnel oxide layer.

6. The method of claim 5, the patterning step comprising the steps of:
forming a photoresist pattern on the first conductive type polysilicon;
etching the first conductive type polysilicon, block oxide layer, trap nitride layer, and tunnel oxide layer using the photoresist pattern as an etch mask; and
removing the photoresist pattern.

7. The method of claim 5, further comprising the step of implanting second type impurities in the substrate using the patterned first conductive type polysilicon, block oxide layer, trap nitride layer, and tunnel oxide layer as an ion implantation mask to form source/drain regions.

8. The method of claim 5, wherein the trap nitride layer is formed 50˜200 Å thick.
